(19) United States
(12) Patent Application Publication
(10) Pub. No.: US 2018/0076413 A1
(43) Pub. Date: Mar. 15, 2018

(54) DISPLAY PANEL AND METHOD FOR PACKAGING THE SAME, AND DISPLAY DEVICE

(71) Applicants: BOE TECHNOLOGY GROUP CO., LTD., Beijing (CN); HEFEI BOE OPTOELECTRONICS TECHNOLOGY CO., LTD., Anhui (CN)

(72) Inventor: Yajun LI, Beijing (CN)

(73) Assignees: BOE TECHNOLOGY GROUP CO., LTD., Beijing (CN); HEFEI BOE OPTOELECTRONICS TECHNOLOGY CO., LTD., Anhui (CN)

(21) Appl. No.: 15/302,992

(22) PCT Filed: Dec. 23, 2015
(86) PCT No.: PCT/CN2015/098379

§ 371 Date: Oct. 9, 2016

(30) Foreign Application Priority Data
Jul. 28, 2015 (CN) 201510455788.X

(51) Int. Cl. H01L 51/52; H01L 51/56

(52) U.S. Cl. CPC H01L 51/5246; H01L 2251/301; H01L 51/56; H01L 51/5253

(57) ABSTRACT

The present disclosure discloses a display panel and a method for packaging the same, and a display device. The display panel includes an organic light-emitting diode (OLED), a base substrate on which the OLED is arranged, a thin film packaging layer arranged on the OLED, a metal blocking layer arranged on the thin film packaging layer and a packaging cover plate arranged on the metal blocking layer.

### CROSS-REFERENCE TO RELATED APPLICATIONS

The present application claims a priority of the Chinese patent application No. 201510455788.X filed on Jul. 28, 2015, which is incorporated herein by reference in its entirety.

### TECHNICAL FIELD

The present disclosure relates to the field of display technology, and in particular to a display panel and a method for packaging the same and a display device.

### BACKGROUND

Organic Light-Emitting Diode (abbreviated as OLED) is a totally new display technology, with display quality comparable to Thin Film Transistor Liquid Crystal Display (abbreviated as TFT-LCD). OLED has steadily become the focus of international research because of its advantages in panel displaying, such as high light-emitting luminance, rich color, low-voltage DC driving and simple preparation process, etc.

In the last 20 years, OLED has been greatly developed, light-emitting materials of red, green and blue colors have been developed successfully with improved life, and full-color displaying with light-emitting intensity and light-emitting efficiency that have reached a practical level has been industrialized. Currently, OLED devices that have a use service life over 10,000 hours and a storage service life over 50,000 hours have been manufactured, but compared to liquid crystal display (LCD) and Plasma Display Panel (abbreviated as PDP), relatively short service life remains one of important factors that constrain OLED commercialization.

There are many factors that affect the service life of OLED, mainly physical impacts and chemical impacts. Wherein the physical impacts mainly comprise a combination of functional layers and interfaces between each other, cathode material, glass transition temperature of Hole Transport Layer (abbreviated as HTL), driving way and so on. The chemical impacts mainly comprise: oxidization of cathode, crystallization of Hole Transport Layer and the like. These factors will affect the service life of OLED. In practical applications, moisture and oxygen in the air greatly affect the service life of OLED mainly because electrons are injected from the cathode when an OLED device works, which requires a cathode work function as low as possible, but metal for making the cathode (such as aluminum, magnesium, calcium, etc.) is generally active, easily to react with moisture that permeates therein. Further, moisture also may chemically react with Hole Transport Layer and Electron Transport Layer (abbreviated as ETL), and these reactions may cause the OLED device to fail.

Therefore, if an OLED device is effectively packaged, making respective functional layers of the OLED device separate from moisture, oxygen and other components in the atmosphere, the service life of the OLED device may be greatly extended. However, the related art does not provide an effective solution.

### SUMMARY

The main purpose of the present disclosure is to provide an OLED packaging technical solution that may avoid the case where an OLED device after package is easily in contact with water and oxygen, which shortens the use service life of the OLED device.

To achieve the above purpose, the present disclosure provides a display panel and a packaging method thereof, and a display device.

In one aspect of the present disclosure, a display panel is provided, including an organic light-emitting diode (OLED), a base substrate on which the OLED is arranged, a thin film packaging layer arranged on the OLED, a metal blocking layer arranged on the thin film packaging layer and a packaging cover plate arranged on the metal blocking layer.

Optionally, the metal blocking layer is formed on the thin film packaging layer through injection.

Optionally, a material of the metal blocking layer is gallium, indium, or gallium indium alloy.

Optionally, the display panel further includes a sealant, arranged between the base substrate and the packaging cover plate, and configured to seal the OLED, the thin film packaging layer and the metal blocking layer.

Optionally, the base substrate, the OLED, the thin film packaging layer, the metal blocking layer and the packaging cover plate are arranged along a first direction in sequence.

The first direction is perpendicular to the base substrate and from the base substrate to the packaging cover plate.

In another aspect of the present disclosure, a display device is provided, including the display panel hereinabove.

In another aspect of the present disclosure, a method for packaging a display panel is provided, including forming a thin film packaging layer on a base substrate on which an organic light-emitting diode (OLED) is arranged; forming a metal blocking layer on the thin film packaging layer; and arranging a packaging cover plate on the metal blocking layer.

Optionally, the step of forming a metal blocking layer on the thin film packaging layer includes forming the metal blocking layer on the thin film packaging layer through injection.

Optionally, a material of the metal blocking layer is gallium, indium, or gallium indium alloy.

Optionally, prior to forming the metal blocking layer, the method further includes coating a sealant at a predetermined position of the base substrate.

Optionally, subsequent to forming the metal blocking layer, the method further includes coating a sealant at a predetermined position of the packaging cover plate or the base substrate while arranging the packaging cover plate, so as to seal the OLED, the thin film packaging layer and the metal blocking layer.

Compared with the prior art, and compared to a plurality of packaging processes like inorganic film packaging, organic film packaging, inorganic-organic composite film packaging, the display panel and packaging method thereof according to the present disclosure may form an effective blocking to moisture and oxygen, thereby avoiding damages from moisture and oxygen to the OLED device.

### BRIEF DESCRIPTION OF THE DRAWINGS

FIG. 1 is a schematic view of a display panel in some embodiments of the present disclosure;

FIG. 2 is a flowchart of a method for packaging a display panel in some embodiments of the present disclosure.

### DETAILED DESCRIPTION OF THE EMBODIMENTS

The technical solution in some embodiments of the present disclosure will be clearly and completely described below in conjunction with the accompanying drawings in some embodiments of the present disclosure. Obviously, the described embodiments are merely part of, instead of all of, the embodiments of the present disclosure. Based on the embodiments in the present disclosure, all other embodiments obtained by those of ordinary skill in the art, without creative work, are within the scope of the present disclosure sought for protection.

Currently, the aging of OLED devices is caused mainly because most of organic material of the light-emitting layer are very sensitive to pollutants, oxygen and moisture in the atmosphere. The main factors that reduce the service life of OLED are: (1) most of metal material of an OLED cathode are metals with active chemical properties, prone to erosion in the air or other oxygen-containing environment, particularly to electrochemical corrosion in a moisture-containing environment. The OLED cathode material is generally manufactured by a physical vapor deposition, in which fine dust particles adhere on the organic function layer, easily make the cathode material generate pinholes, and hence become a channel through which moisture and oxygen are in contact with the organic functional layer; (2) the carbonyl compound generated by oxidation of oxygen with the light-emitting layer is an effective quencher, which can significantly reduce light-emitting quantum efficiency of the OLED. Moisture may cause the organic layer compound to hydrolyze and affect the electrical conducting performance, thereby leading to a great decrease in stability; (3) heat generated when the OLED works will further increase the aging of light-emitting materials, auxiliary materials, electrodes etc. of the OLED device in the air, further affecting the service life of the device. To make the service life of the OLED device meet practical requirements, it is generally required that moisture permeability for the device packaging is less than 10-6 g/(m2·d) and oxygen permeability is less than 10-3 g/(m2·d). In practical applications, when the cathode is corroded by 10%, the operation of the device will be seriously affected.

These factors need to be considered in OLED device packaging. Current OLED device packaging mainly adopt thin film packaging, while the thin film packaging comprises inorganic film packaging, organic film packaging, inorganic-organic film composite packaging and other processes, but these processes have a common flaw that it is hard to avoid the defects of the film itself, leading to poor blocking ability of moisture and oxygen. Therefore, using conventional thin film packaging to package the OLED will greatly reduce the service life of the OLED device.

In view of this, it is to provide a method for packaging an OLED. According to the packaging method, a metal layer is formed on a thin film layer relatively easily permeable to moisture and oxygen. Since metal is composed of atoms, and oxygen or moisture can hardly permeate through the tightly combined atoms, thereby the blocking of oxygen and moisture is effectively improved, so that the OLED device will not be affected by moisture and oxygen and have an improved service life.

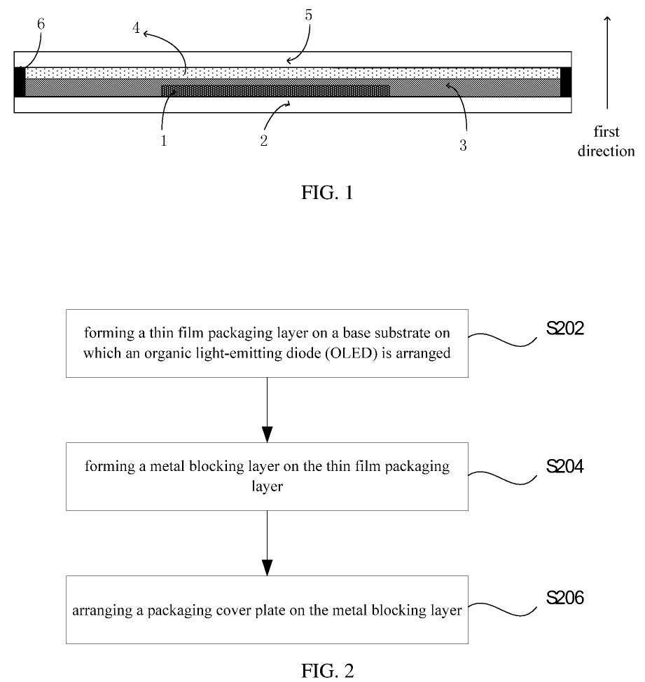

A display panel is provided in some embodiments of the present disclosure. FIG. 1 is a schematic view of a display panel in some embodiments of the present disclosure. As shown in FIG. 1, the display panel includes an organic light-emitting diode (OLED) 1, a base substrate 2 on which the OLED 1 is arranged, a thin film packaging layer 3 arranged on the OLED 1, a metal blocking layer 4 arranged on the thin film packaging layer 3 and a packaging cover plate 5 arranged on the metal blocking layer 4.

The organic material film layers, inorganic film layers, even organic-inorganic hybrid film layers in the related art mostly consist of macromolecule polymer, these materials themselves have a relatively large porosity, and some materials even have great elasticity. In contrast, the metal material is composed of atoms directly which are tightly combined, and its porosity is much smaller than the porosity of the above materials, or even negligible. Thus, the metal blocking layer formed of a metal material can effectively avoid the permeation of moisture and oxygen, thereby greatly improving tightness of the OLED device packaging.

In practical applications, in view of the operating temperature range of OLED device and the maximum temperature that the OLED device can withstand during packaging, in order not to affect the OLED or in order to reduce the impact on the OLED as much as possible, the process temperature for forming the metal blocking layer 4 should be as low as possible. For example, metal forming processes under a temperature below 200 degrees may be selected. Of course, this also considers such as low temperature metal forming process selected because conventional metal plating layers have defects like complicated process, great difficulty, and demand for high temperature

In some embodiments of the present disclosure, the metal blocking layer 4 is formed on the thin film packaging layer 3 through injection. The melting point of the metal is required to be low if the metal is injected in the liquid state, and this is just to decrease the process temperature of forming the metal blocking layer 4 as much as possible so as to reduce the adverse influence on the OLED.

In some embodiments of the present disclosure, the material of the metal blocking layer 4 may include gallium, indium, or gallium indium alloy. Since the melting points of these metal materials are relatively low, for example, the melting point of gallium is 29.8° C., the melting point of indium is 156.61° C., and the melting point of gallium indium alloy varies with the proportion of composition of gallium and indium and is between the melting point of gallium and the melting point of indium. During the OLED device packaging, the process temperature that the OLED device can withstand is generally from 100° C. to 200° C., whereby the process temperature when these materials are used to form the metal blocking layer 4 does not greatly affect the OLED.

Of course, if it is to choose a metal material and process with minimal adverse influence on the OLED, gallium is very appropriate. Gallium exhibits a liquid state at 29.8° C. or more, whereby it is easy to inject the gallium when it is in the liquid state, almost without any adverse influence on the OLED at such temperature condition.

For ease of understanding, gallium will be briefly introduced. The metal gallium is a silvery white rare metal, with density of 5.904 g/cc, a melting point of 29.78° C., and boiling point of 2403° C. The metal gallium forms liquid at about 30° C. and may be added directly to the thin film packaging layer 3 as a filler to form the metal blocking layer, through simple and achievable operations. After the addition is completed, whether in a solid or liquid state, it can play a role of effectively blocking oxygen and moisture.

In practical applications, the operating temperature range of OLED device is generally from −20° C. to 70° C., so when a display device operates, a metal blocking layer 4 constituted by gallium may be in a solid state and may also be in a liquid state, a metal blocking layer 4 constituted by indium is definitely in a solid state, while a metal blocking layer 4 constituted by gallium indium alloy may be in a solid state and may also be in a liquid state, depending of course on the proportion of composition of gallium and indium.

In some embodiments of the present disclosure, the display panel further comprises: a sealant 6 arranged between the substrate 2 and the packaging cover plate 5 for sealing the OLED 1, the thin film packaging layer 3 and the metal blocking layer 4.

Some embodiments of the present disclosure further provide a display device, comprising the display panel in the above-described embodiment. Since the improvement of the display device lies in the display panel, the display device will no longer be described in combination with the accompanying drawings.

A method for packaging a display panel is provided in some embodiments of the present disclosure. FIG. 2 is a flowchart of a method for packaging a display panel in some embodiments of the present disclosure. As shown in FIG. 2, the method includes the following steps (steps S202-S206):

Step S202: forming a thin film packaging layer on a base substrate on which an organic light-emitting diode (OLED) is arranged;

Step S204: forming a metal blocking layer on the thin film packaging layer; and

Step S206: arranging a packaging cover plate on the metal blocking layer.

In some embodiments of the present disclosure, Step S204 may further include: injecting the metal blocking layer on the thin film packaging layer by injection, thereby avoiding or reducing damages of the OLED device due to the high temperature.

In some embodiments of the present disclosure, the material of the metal blocking layer may include: gallium, indium, or gallium indium alloy. The reasons of selecting these materials have been described hereinabove, and the detailed description thereof is omitted herein.

In some embodiments of the present disclosure, the sealant may be formed in the following two ways:

(1) Prior to Step S204, a sealant may be coated at a predetermined position of the substrate. In this way, the sealant coated on the base substrate may firstly form a structure similar to a container with an opening, then the metal blocking layer is formed in an inner region of the structure formed by the sealant on the substrate, especially very suitable for the ion injecting way, thereafter a cover plate is covered to cure the sealant. Since the operation duration is very short, and the volume of the metal material injected as ion must be previously calculated, an effective seal may be formed after the entire liquid metal is paved smoothly on the thin film packaging layer.

(2) Subsequent to Step S204, a sealant may be coated at a predetermined position of the packaging cover plate or the base substrate while the packaging cover plate is arranged, so as to seal the OLED, the thin film packaging layer and the metal blocking layer.

In this way, the metal blocking layer is formed first, then the sealant is coated, and since the operation duration is very short, it is possible to form an effective seal.

According to the embodiments of the present disclosure, a dense metal layer is arranged on a film layer. In compared with inorganic film packaging, organic film packaging, inorganic-organic film composite packaging and other packaging process, it is able to effective block the moisture and oxygen, thus avoiding damages of the OLED device due to moisture and oxygen.

The foregoing is merely some embodiments of the present disclosure. It should be noted that those of ordinary skill in the art may further make a number of improvements and modifications, without departing from the principles of the present disclosure, which improvements and modifications also should be considered to be included within the scope of the present disclosure sought for protection.

1. A display panel, comprising:
an organic light-emitting diode (OLED), a base substrate on which the OLED is arranged, a thin film packaging layer arranged on the OLED, a metal blocking layer arranged on the thin film packaging layer and a packaging cover plate arranged on the metal blocking layer.

2. The display panel according to claim 1, wherein the metal blocking layer is formed on the thin film packaging layer through injection.

3. The display panel according to claim 2, wherein a material of the metal blocking layer is gallium, indium, or gallium indium alloy.

4. The display panel according to claim 1, further comprising:
a sealant, arranged between the base substrate and the packaging cover plate, and configured to seal the OLED, the thin film packaging layer and the metal blocking layer.

5. The display panel according to claim 1, wherein the base substrate, the OLED, the thin film packaging layer, the metal blocking layer and the packaging cover plate are arranged along a first direction in sequence;
wherein the first direction is perpendicular to the base substrate and from the base substrate to the packaging cover plate.

6. A display device, comprising the display panel according to claim 1.

7. A method for packaging a display panel, comprising:
forming a thin film packaging layer on a base substrate on which an organic light-emitting diode (OLED) is arranged;
forming a metal blocking layer on the thin film packaging layer; and arranging a packaging cover plate on the metal blocking layer.

8. The method according to claim 7, wherein the step of forming a metal blocking layer on the thin film packaging layer comprises:
forming the metal blocking layer on the thin film packaging layer through injection.

9. The method according to claim 8, wherein a material of the metal blocking layer is gallium, indium, or gallium indium alloy.

10. The method according to claim 7, wherein prior to forming the metal blocking layer, the method further comprises:
coating a sealant at a predetermined position of the base substrate.

11. The method according to claim 7, wherein subsequent to forming the metal blocking layer, the method further comprises:
coating a sealant at a predetermined position of the packaging cover plate or the base substrate while arranging the packaging cover plate, so as to seal the OLED, the thin film packaging layer and the metal blocking layer.

12. The display panel according to claim 2, further comprising:
a sealant, arranged between the base substrate and the packaging cover plate, and configured to seal the OLED, the thin film packaging layer and the metal blocking layer.

13. The display panel according to claim 3, further comprising:
a sealant, arranged between the base substrate and the packaging cover plate, and configured to seal the OLED, the thin film packaging layer and the metal blocking layer.

14. The method according to claim 8, wherein prior to forming the metal blocking layer, the method further comprises:
coating a sealant at a predetermined position of the base substrate.

15. The method according to claim 9, wherein prior to forming the metal blocking layer, the method further comprises:
coating a sealant at a predetermined position of the base substrate.

16. The method according to claim 8, wherein subsequent to forming the metal blocking layer, the method further comprises:
coating a sealant at a predetermined position of the packaging cover plate or the base substrate while arranging the packaging cover plate, so as to seal the OLED, the thin film packaging layer and the metal blocking layer.

17. The method according to claim 9, wherein subsequent to forming the metal blocking layer, the method further comprises:
coating a sealant at a predetermined position of the packaging cover plate or the base substrate while arranging the packaging cover plate, so as to seal the OLED, the thin film packaging layer and the metal blocking layer.
